(19) United States
(12) Patent Application Publication
(10) Pub. No.: US 2025/0191891 A1
(43) Pub. Date: Jun. 12, 2025

(54) PLASMA PROCESSING APPARATUS AND PLASMA PROCESSING METHOD

(71) Applicant: Tokyo Electron Limited, Tokyo (JP)

(72) Inventor: Masaki HIRAYAMA, Tokyo (JP)

(21) Appl. No.: 18/845,306

(22) PCT Filed: Mar. 6, 2023
(86) PCT No.: PCT/JP2023/008285

§ 371 Date: Sep. 9, 2024

(30) Foreign Application Priority Data
Mar. 18, 2022 (JP) 2022-043534

(51) Int. Cl. H01J 37/32

(52) U.S. Cl. CPC H01J 37/32522; H01J 37/32128; H01J 37/3244; H01J 37/32568; H01J 2237/002; H01J 2237/332

(57) ABSTRACT

A plasma processing apparatus includes a processing container having a processing space where a substrate is disposed; a plasma generation unit including a first electrode and a second electrode which are provided facing each other and are configured as parallel plate electrodes, and having a plasma generating space formed between the first electrode and the second electrode; a radio-frequency power supply unit configured to form a radio-frequency electric field between the first electrode and the second electrode; a gas supply unit configured to supply a processing gas for plasma generation in the plasma generating space; a plasma introduction unit configured to introduce the plasma generated in the plasma generating space to the processing space; and a heat transfer member including an insulator and provided between the first electrode and the second electrode. Plasma processing is performed on the substrate by the plasma introduced to the processing space.

### TECHNICAL FIELD

The present invention relates to a plasma processing apparatus and a plasma processing method.

### BACKGROUND

In the manufacturing process of semiconductor devices, a plasma processing apparatus is used to perform plasma processing on a semiconductor wafer which is a substrate. Patent Document 1 discloses a remote-type plasma processing apparatus, in which a processing container is divided into a reaction chamber where a processing target is placed and a plasma generation chamber, radio-frequency power is applied to an upper electrode to generate plasma in the plasma generation chamber, and the plasma processing is performed by guiding active species in the plasma, to the reaction chamber.

### PRIOR ART DOCUMENT

### Patent Document

Patent Document 1: Japanese Patent Laid-open Publication No. 2020-155387

### SUMMARY OF THE INVENTION

### Problem to be Solved

The present disclosure provides a plasma processing apparatus and a plasma processing method which can perform uniform plasma processing when in a plasma generator, plasma is generated by supplying radio-frequency power to an electrode, and the plasma is guided to a substrate to perform the plasma processing.

### Means to Solve the Problem

A plasma processing apparatus according to an aspect of the present disclosure includes: a processing container having a processing space where a substrate is disposed; a plasma generation unit including a first electrode and a second electrode which are provided facing each other and are configured as parallel plate electrodes, and having a plasma generating space formed between the first electrode and the second electrode; a radio-frequency power supply unit that forms a radio-frequency electric field between the first electrode and the second electrode; a gas supply unit that supplies a processing gas for plasma generation in the plasma generating space; a plasma introduction unit that introduces the plasma generated in the plasma generating space to the processing space; and a heat transfer member including an insulator, and provided between the first electrode and the second electrode so as to thermally connect these. Plasma processing is performed on the substrate by the plasma introduced to the processing space.

### Effect of the Invention

According to the present disclosure, provided are a plasma processing apparatus and a plasma processing method which can perform uniform plasma processing when in a plasma generator, plasma is generated by supplying radio-frequency power to an electrode, and the plasma is guided to a substrate to perform the plasma processing.

### BRIEF DESCRIPTION OF THE DRAWINGS

FIG. 1 is a cross-sectional view schematically illustrating a plasma processing apparatus according to a first embodiment.

FIG. 2 is a cross-sectional view illustrating a main part of the plasma processing apparatus of FIG. 1 in detail.

FIG. 3 is a cross-sectional view illustrating a main part of a plasma processing apparatus according to a second embodiment.

FIG. 4 is a cross-sectional view illustrating a main part of a plasma processing apparatus according to a third embodiment.

FIG. 5 is a cross-sectional view illustrating a main part of a plasma processing apparatus according to a fourth embodiment.

### DETAILED DESCRIPTION TO EXECUTE THE INVENTION

Hereinafter, embodiments will be described with reference to accompanying drawings.

### First Embodiment

First, a first embodiment will be described.

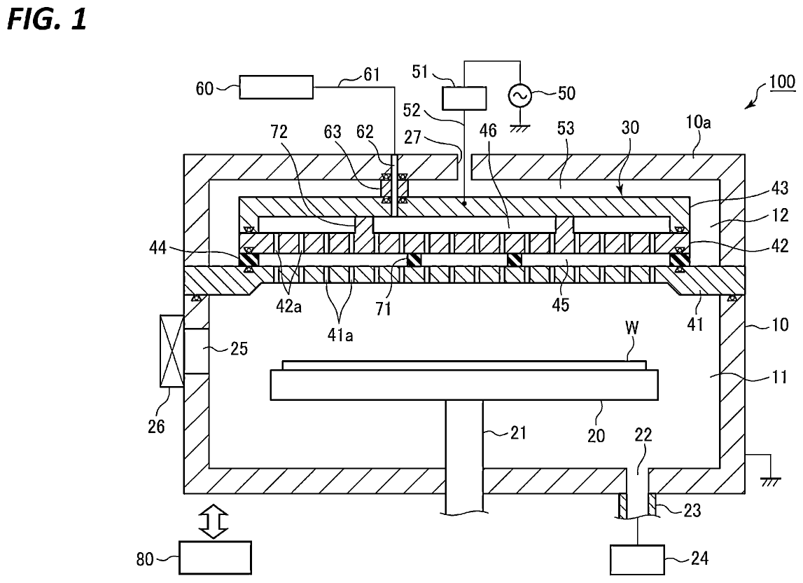

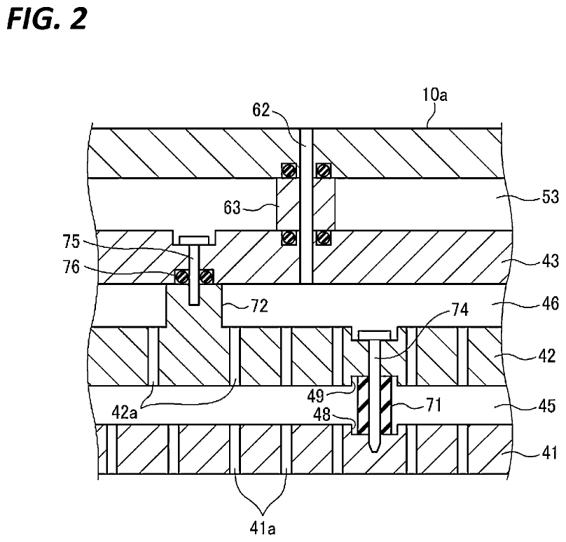

FIG. 1 is a cross-sectional view schematically illustrating a plasma processing apparatus according to a first embodiment, and FIG. 2 is a cross-sectional view illustrating its main part in detail.

A plasma processing apparatus 100 of the present embodiment performs plasma processing on a substrate W. The plasma processing is not particularly limited, but film formation processing such as CVD or ALD is exemplified.

The plasma processing apparatus 100 has a processing container 10 that is substantially cylindrical, and is made of metal, for example, metal such as aluminum whose surface is anodized. The inside of the processing container 10 is divided into a lower space 11 and an upper space 12, and the lower space 11 functions as a processing space. Also, the plasma processing apparatus 100 has a plasma generator 30.

A stage 20 on which the substrate W is placed is provided in the lower space 11. The stage 20 is supported by a support member 21. The support member 21 extends downward through the bottom wall of the processing container 10, and can be raised and lowered by an elevating mechanism (not illustrated). A sealing mechanism (not illustrated) is provided between the support member 21 and the bottom wall of the processing container 10. The stage 20 and the support member 21 are made of, for example, metal, for example, metal such as aluminum whose surface is anodized. The stage 20 is provided with an elevating pin (not illustrated) that moves up and down while protruding or retreating from the surface of the stage 20 so that the substrate W is transferred. Also, the stage 20 may be provided with an electrostatic chuck for electrostatically attracting the substrate W, and a temperature control mechanism such as a heater.

An exhaust port 22 is formed in the bottom of the processing container 10, and an exhaust pipe 23 is connected to the exhaust port 22. An exhaust device 24 including a vacuum pump, a pressure control valve, etc. is connected to the exhaust pipe 23. Then, by operating the exhaust device 24, the lower space 11 which is a processing space is exhausted, and the lower space 11 is maintained at a predetermined degree of vacuum. Also, a loading/unloading port 25 for loading and loading the substrate W is formed in the side wall of the processing container 10, and the loading/unloading port 25 can be opened and closed by a gate valve 26.

The plasma generator 30 is provided in the upper space 12, and is configured as a shower head having a lower shower plate 41 as a lower electrode, an upper shower plate 42 as an upper electrode, and a sealing plate 43 provided on the upper shower plate 42. The lower shower plate 41 as a lower electrode and the upper shower plate 42 as an upper electrode constitute parallel plate electrodes, and a space between these becomes a plasma generating space 45.

The lower shower plate 41 and the upper shower plate 42 are made of metal such as aluminum alloy, titanium, and stainless steel, are formed in disk shapes, and are stacked at a distance through an insulating ring 44 provided at an outer periphery. The insulating ring 44 is made of an insulator such as alumina, quartz, yttria, and Teflon (registered trademark), and a gap between the insulating ring 44 and the lower shower plate 41 and a gap between the insulating ring 44 and the upper shower plate 42 are sealed by sealing members such as a seal ring (O ring).

The lower shower plate 41 has a plurality of gas holes 41a formed therethrough in the vertical direction, and the upper shower plate 42 has a plurality of gas holes 42a formed therethrough in the vertical direction. As described below, an interval between the lower shower plate 41 and the upper shower plate 42, that is, an interval between the parallel plate electrodes (electrode interval) may be set such that a quasi-TEM wave is obtained according to the frequency.

The lower shower plate 41 has a function of dividing the inside of the processing container 10 into the lower space 11 and the upper space 12, and is attached to the side wall of the processing container 10. A gap between the lower surface of the lower shower plate 41 and the side wall of the processing container 10 is sealed by a sealing member such as a seal ring (O ring), and the inside of the lower space 11 which is a processing space is kept airtight.

The sealing plate 43 is made of metal such as aluminum alloy, titanium, and stainless steel, and has a function of sealing the upper shower plate 42 and defining an air atmosphere and a vacuum atmosphere. The outer edge of the sealing plate 43 protrudes downward, and a gap between the outer edge of the sealing plate 43 and the upper shower plate 42 is sealed by a sealing member such as a seal ring (O ring). The space between the sealing plate 43 and the upper shower plate 42 becomes a gas diffusion space 46.

The plasma processing apparatus 100 further includes a radio-frequency power supply 50 and a gas supply 60.

The radio-frequency power supply 50 forms a radio-frequency electric field between the lower shower plate 41 which is a lower electrode and the upper shower plate 42 which is an upper electrode. A power feeding line 52 extending from the radio-frequency power supply 50 is connected to the sealing plate 43 via a radio-frequency introduction unit 27 provided on a ceiling wall 10a of the processing container 10. A matching unit 51 is interposed in the power feeding line 52. The high frequency wave from the radio-frequency power supply 50 is applied to the upper shower plate 42 which is an upper electrode via the sealing plate 43, and a radio-frequency electric field is formed in the plasma generating space 45 between the lower shower plate 41 and the upper shower plate 42 constituting the parallel plate electrodes. The frequency of the radio-frequency power supply 50 is not particularly limited as long as plasma can be generated, but a VHF to UHF band is suitable (in a range of hundreds of kHz to hundreds of MHz). A space around the power feeding line 52 between the ceiling wall of the processing container 10 and the sealing plate 43 becomes a radio-frequency propagation portion 53.

The gas supply 60 supplies, for example, a processing gas for performing plasma processing, and an inert gas for pressure adjustment or purging. When the plasma processing is film formation processing such as CVD or ALD, as for the processing gas, a film-forming raw material gas and a reaction gas are used. When a film is formed by a thermal decomposition reaction of the film-forming raw material gas, only the film-forming raw material gas may be supplied as the processing gas. A gas supply pipe 61 extends from the gas supply 60, and the gas supply pipe 61 is connected to a gas introduction path 62. The gas introduction path 62 is connected to the gas diffusion space 46 via the ceiling wall 10a of the processing container 10, a spacer 63 provided between the ceiling wall 10a and the sealing plate 43, and the sealing plate 43. Therefore, the processing gas supplied from the gas supply 60 reaches the plasma generating space 45 via the gas supply pipe 61, the gas introduction path 62, the gas diffusion space 46, and the gas holes 42a. Then, capacitively coupled plasma is generated in the plasma generating space 45 by the radio-frequency electric field formed between the upper shower plate 42 and the lower shower plate 41. The plasma generated in the plasma generating space 45 is composed of active species or charged particles, and only the active species, or the active species and charged particles are introduced from the gas holes 41a to the lower space 11 which is a processing space. That is, the gas holes 41a function as a plasma introduction unit that introduces only the active species, or the active species and charged particles in the plasma generating space 45, to the lower space 11 which is a processing space.

A lower heat transfer member 71 made of an insulator is provided between the upper shower plate 42 and the lower shower plate 41 so as to thermally connect these. In the example of FIG. 1, a plurality of (for example, six) lower heat transfer members 71 is provided. The lower heat transfer members 71 may be suitably provided at axially symmetrical positions. For example, one lower heat transfer member 71 may be provided at the center. The lower heat transfer member 71 has a function of dissipating heat applied from plasma to the lower shower plate 41, by heat transfer.

Since capacitively coupled plasma is generated between the lower shower plate 41 and the upper shower plate 42, the lower heat transfer member 71 needs to be an insulator. As for the insulator constituting the lower heat transfer member 71, an insulator having high thermal conductivity may be used so that heat can be effectively released by heat transfer. Examples of such an insulator having high thermal conductivity may include aluminum nitride (AlN), alumina (Al₂O₃), silicon carbide (SiC), quartz glass, and yttria (Y₂O₃). Among these, in particular, AlN having high thermal conductivity may be suitably used. The insulator constituting the lower heat transfer member 71 may be a resin, and, for example, a resin having high thermal conductivity, such as polyimide, polyphenylene sulfide, and polyether ether ketone may be used. The thermal conductivity of the lower heat transfer member 71 may be selected according to a usage temperature, and for example, a material having a thermal conductivity of 100 W/K·m or more at a usage temperature ranging from 20 to 200° C. is preferred. Such high thermal conductivity may be achieved by the above mentioned AlN.

As illustrated in FIG. 2 in detail, the lower heat transfer member 71 is fitted into a recess 48 formed in the upper surface of the lower shower plate 41 and a recess 49 formed in the lower surface of the upper shower plate 42. Then, the lower heat transfer member 71 is fastened while, for example, a screw 74 including an insulator such as AlN, Al₂O₃, and SiC is screwed into the lower shower plate 41 from the top side of the upper shower plate 72 through the lower heat transfer member 71.

A metallic upper heat transfer member 72 is provided between the upper shower plate 42 and the sealing plate 43 so as to thermally connect these. In the example of FIG. 1, a plurality of (for example, six) upper heat transfer members 72 is provided. The upper heat transfer members 72 are suitably provided at axially symmetrical positions. For example, one upper heat transfer member 72 may be provided at the center. The upper heat transfer member 72 has a function of guiding heat transferred to the upper shower plate 42, to the sealing plate 43. The space above the sealing plate 43 is in an air atmosphere, and the heat transferred from the upper heat transfer member 72 to the sealing plate 43 is removed by thermal convection, etc.

The upper heat transfer member 72 includes, for example, the same material as the upper shower plate 42 and is configured integrally with the upper shower plate 42. As illustrated in FIG. 2 in detail, the upper heat transfer member 72 and the sealing plate 43 are fastened by a metallic screw 75, and a gap between the upper heat transfer member 72 and the sealing member 43 may be sealed by a sealing member 76 such as a seal ring (O ring). Also, the upper heat transfer member 72 may be a separate member from the upper shower plate 42.

The plasma processing apparatus 100 further includes a controller 80. The controller 80 controls valves, etc. of the exhaust device 24, the radio-frequency power supply 50, and the gas supply 60 which are components of the plasma processing apparatus 100. The controller 80 includes a main controller having a CPU, an input device, an output device, a display device, and a storage device. Then, the processing of the plasma processing apparatus 100 is controlled on the basis of a processing recipe stored in a storage medium of the storage device.

Next, descriptions will be made on a processing operation by the plasma processing apparatus 100 configured as above.

First, the substrate W is carried into the lower space 11 which is a processing space of the processing container 10, and is placed on the stage 20. Next, while an inert gas is supplied from the gas supply 60 to the lower space 11 through the plasma generation unit 30 constituting the shower head, the exhaust device 24 exhausts the lower space 11 and performs pressure adjustment so that a desired vacuum atmosphere is obtained.

In this state, a processing gas is supplied from the gas supply 60 to the plasma generation unit 30 constituting the shower head, and radio-frequency power is applied from the radio-frequency power supply 50 to the upper shower plate 42 which is an upper electrode via the sealing plate 43.

Specifically, by applying radio-frequency power to the upper shower plate 42, a radio-frequency electric field is formed in the plasma generating space 45 between the lower shower plate 41 which is a lower electrode and the upper shower plate 42 which is an upper electrode. Also, by supplying the processing gas to the plasma generation unit 30, the processing gas reaches the plasma generating space 45 from the gas diffusion space 46 via the gas holes 42a, and the radio-frequency electric field generates capacitively coupled plasma in the plasma generating space 45. The generated plasma is composed of active species or charged particles, and only the active species, or the active species and the charged particles are introduced from the gas holes 41a functioning as the plasma introduction unit to the lower space 11 which is a processing space, and are supplied to the substrate W so that the substrate W is processed.

Here, when plasma is generated in the plasma generating space 45, ions and electrons in the plasma enter the upper surface of the lower shower plate 41 and the lower surface of the upper shower plate 42. The entering ions and electrons have kinetic energy, and impart heat to these surfaces when colliding with these surfaces. Also, when the substrate W on the stage 20 is heated, heat is also imparted to the lower shower plate 41 and the upper shower plate 42 from the substrate W.

Meanwhile, as the semiconductor manufacturing technology advances, high performance of a plasma processing apparatus is required. In particular, in a plasma processing apparatus for film formation such as CVD or ALD, there is a demand for productivity improvement based on an increase of the density of active species or the plasma density in the gas phase. In a remote-type plasma processing apparatus such as that in the present embodiment, when large power is input to improve productivity, the amount of heat given to the lower surface of the upper shower plate 42 and the upper surface of the lower shower plate 41 increases in proportion to the input power. For this reason, if the temperatures of the upper surface of the lower shower plate 41 and the lower surface of the upper shower plate 42 are increased and the lower heat transfer member 71 does not exist, due to a difference in thermal expansion, there is a risk that the upper shower plate 42 may be warped while protruding downwards, and the lower shower plate 41 may be warped while protruding upwards. In this manner, if warpage occurs in the lower shower plate 41 which is a lower electrode and the upper shower plate 42 which is an upper electrode, the distance (electrode interval) between these is not kept constant, and the generated plasma becomes non-uniform.

In particular, when the frequency of the radio-frequency power is increased to, for example, 180 MHz or more in order to increase the density of active species or the plasma density and thereby achieve the efficiency of plasma processing, as described below, an electrode interval at which a quasi-TEM wave required for generating uniform plasma is obtained is reduced, for example, to 2 to 3 mm. In this manner, when the electrode interval is reduced, the rate of variation in the electrode interval is relatively increased. The variation is caused by warpage occurring in the lower shower plate 41 which is a lower electrode and the upper shower plate 42 which is an upper electrode. Then, the impact imparted to the plasma uniformity becomes large.

In order to suppress such warpage of electrodes, it is effective to effectively perform heat extraction of the lower electrode and the upper electrode, and for that purpose, it is thought that it is effective to increase thicknesses of the lower electrode and the upper electrode and to reduce their thermal resistance in the radial direction. Also, it is thought that it is also effective to provide a coolant passage inside the electrode and to extract heat by the coolant. In any case, according to a conventional technical common sense, in order to effectively extract heat, there is no choice but to increase the thicknesses of the lower electrode and the upper electrode.

However, in the remote-type plasma processing apparatus, since active species or charged particles in the plasma generated in the plasma generating space are discharged to the processing space through the gas holes of the lower shower plate which is a lower electrode, if the lower electrode is thick, the gas holes become longer, and the active species or charged particles are easily deactivated. Thus, even if a large current is input, it is difficult to improve productivity.

Therefore, in the present embodiment, the lower heat transfer member 71 made of an insulator is provided between the lower shower plate 41 which is a lower electrode and the upper shower plate 42 which is an upper electrode so as to thermally connect these. This makes it possible to dissipate heat through the lower heat transfer member 71 while maintaining insulation between the lower shower plate 41 and the upper shower plate 42.

Specifically, the heat that has flowed to the lower shower plate 41 is transferred to the upper shower plate 42 through the lower heat transfer member 71. Then, the heat that has flowed to the upper shower plate 42 is transferred to the sealing plate 43 through the upper heat transfer member 72. Since the space above the sealing plate 43 is in an air atmosphere, the heat that has flowed to the sealing plate 43 is removed by thermal convection, etc.

In this manner, since the lower heat transfer member 71 is provided to perform heat extraction, even if large power is input, it is possible to effectively remove the heat of the lower shower plate 41 and the upper shower plate 42. Thus, it is possible to suppress warpage of the lower shower plate 41 and the upper shower plate 42 which are a lower electrode and an upper electrode. Therefore, the distance (electrode interval) between the lower shower plate 41 and the upper shower plate 42 can be kept as constant as possible. Then, it is possible to suppress non-uniformity of plasma and to perform uniform plasma processing on the substrate W. In particular, when the frequency of radio-frequency power is high, it is advantageous to reduce the electrode interval as mentioned above, but even if the influence of the variation of the electrode interval is large, the heat is effectively released by the lower heat transfer member 71. Then, it is possible to suppress the variation of the electrode interval and to perform uniform plasma processing. In this manner, since the heat of the lower shower plate 41 and the upper shower plate 42 can be effectively removed, it is possible to suppress warpage even if these are made thin, and also to suppress deactivation of active species passing through the gas holes 41a.

Also, even if the temperatures of the lower shower plate 41 and the upper shower plate 42 rise and these are slightly warped due to incidence of ions and electrons in the plasma in the plasma generating space 45, the warpage acts in a direction in which the lower heat transfer member 71 is interposed therebetween. Therefore, the lower heat transfer member 71 is in close contact with the lower shower plate 41 and the upper shower plate 42, and then a thermal contact resistance between these is reduced, and heat is more effectively released so as to prevent further warpage. Furthermore, the lower heat transfer member 71 may physically maintain a constant interval between the lower shower plate 41 and the upper shower plate 42. Therefore, even if a force intended to cause deformation acts on the lower shower plate 41 and the upper shower plate 42, the lower heat transfer member 71 suppresses the interval between these from changing. This makes it easy to generate uniform and stable plasma in the plasma generating space 45.

Furthermore, by using an insulator having high thermal conductivity such as AlN, Al₂O₃, SiC, quartz glass, and Y₂O₃, as for the lower heat transfer member 71, the effect of dissipating heat by heat transfer can be improved. Also, the thermal conductivity of the insulator constituting the lower heat transfer member 71 may be selected according to the usage temperature, and in particular, for example, preferred is a material having high thermal conductivity of 100 W/K·m or more at a usage temperature ranging from 20 to 200° C. AlN may be suitably used as such an insulator having high thermal conductivity.

The number and arrangement of the lower heat transfer members 71 are not particularly limited, and may be set in consideration of the uniformity of plasma and the heat transfer effect. The number may be one or more. When a plurality of lower heat transfer members 71 is present, it is possible to uniformly dissipate heat by arranging these at axially symmetrical positions.

Next, descriptions will be made on an interval between the lower shower plate 41 and the upper shower plate 42 constituting the parallel plate electrodes.

From the viewpoint of generating uniform plasma, it is desirable to propagate the high frequency wave as a quasi-TEM wave. If a mode other than the quasi-TEM wave appears, the uniformity of plasma deteriorates. In order to propagate the radio-frequency power as a quasi-TEM wave, the interval (electrode interval) d between the lower shower plate 41 and the upper shower plate 42 constituting the parallel plate electrodes needs to be made smaller than the skin depth of plasma. If the electrode interval d becomes larger than the skin depth of plasma, a mode other than the quasi-TEM wave appears. Also, in order to obtain higher plasma uniformity, it is effective that the quasi-TEM wave has a long wavelength. From this point of view, it is desirable to make the electrode interval d sufficiently smaller than the skin depth of plasma.

This point will be described in more detail.

The wavelength (λ) of the quasi-TEM wave is approximately expressed by the following formula (1) (P.Chabert, J.-L.Raimbault, J.-M.Rax, and A.Perret, “Suppression of the standing wave effect in high frequency capacitive discharges using a shaped electrode and dielectric lens: Self-consistent approach,” PHYSICSOF PLASMAS, 11, 8(2004).).

$$λ = 40 {λ}_{0} {V}_{0}^{1 / 10} {d}^{- 1 / 2} {f}^{2 / 5} \qquad ( 1 )$$

Here, λ₀ is the wavelength (m) in a vacuum, V₀ is the amplitude (V) of a high frequency wave, and f is a frequency (Hz). In the case of circular electrodes, between the electrodes, a standing wave is formed with the electrode center as an antinode. At the radial position r, the voltage V(r) between the electrodes is expressed by the following formula (2).

$$V ( r ) = {V}_{0} {J}_{0} ( k r ) \qquad ( 2 )$$

Here, J₀ is the 0th order Bessel function of the first kind, and k is a wave number. When the radius of the substrate is R, in order to make, for example, 0.8V(0)<V(R), λ>9.8R is obtained from the above formula (2). By inputting this in the formula (1), the following formula (3) is obtained.

$$d < 17 {( {λ}_{0} / R )}^{2} {V}_{0}^{1 / 5} {f}^{4 / 5} \qquad ( 3 )$$

From the formula (3), it is inferred that as the frequency increases, the electrode interval d needs to be set to be smaller. For example, at f=100 MHz, it is inferred that it is desirable that the electrode interval d is made smaller than 7 mm in order to obtain sufficiently uniform plasma.

### Second Embodiment

Next, a second embodiment will be described.

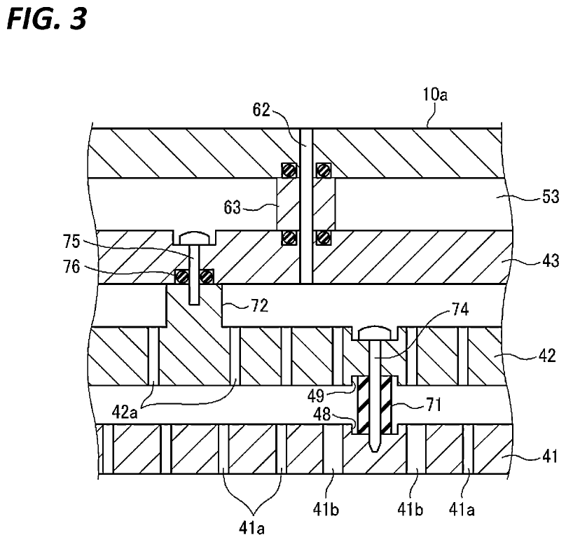

FIG. 3 is a cross-sectional view illustrating a main part of a plasma processing apparatus according to the second embodiment.

In the present embodiment, as illustrated in FIG. 3, the diameter of gas holes 41b of the lower shower plate 41 in the peripheral portion of the lower heat transfer member 71 is formed to be larger than that of the other normal gas holes 41a. Other configurations are the same as those in the first embodiment, and thus descriptions thereof will be omitted.

When an insulator exists in the plasma generating space, charged particles in the plasma disappear in the peripheral portion of the insulator. Therefore, in the peripheral portion of the insulator existing in the plasma generating space, the plasma density is lower than in other portions. Therefore, if the diameters of gas holes are uniform, the amount of active species released from the gas holes around the insulator becomes less than the amount of active species released from other gas holes. In some cases, the uniformity of distribution of active species may become insufficient in the lower space 11 which is a processing space. In this case, uniform plasma processing cannot be necessarily performed on the substrate W.

Therefore, in the present embodiment, in the lower shower plate 41, the diameter of the gas holes 41b in the peripheral portion of the lower heat transfer member 71 which is an insulator is made larger than that of the other gas holes 41a. This makes it possible to suppress deactivation of the active species, in the gas holes 41b, and to compensate for the decrease in the amount of active species released from the gas holes in the peripheral portion of the lower heat transfer member 71. Then, the distribution of active species becomes uniform in the lower space 11 so that uniform plasma processing may be performed on the substrate W.

### Third Embodiment

Next, a third embodiment will be described.

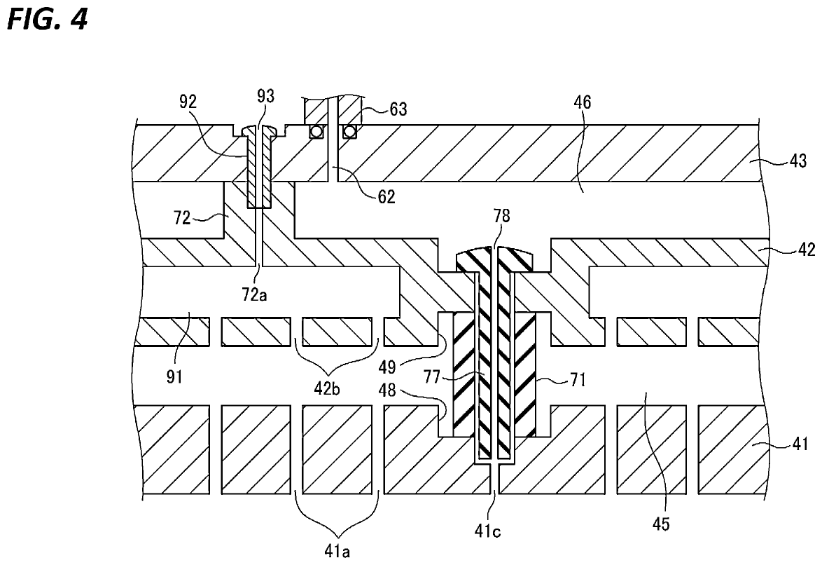

FIG. 4 is a cross-sectional view illustrating a main part of a plasma processing apparatus according to the third embodiment.

In the present embodiment, as illustrated in FIG. 4, in the configuration of the upper shower plate 42, a gas flow path 91 is present inside. A plurality of gas holes 42b extending from the gas flow path 91 and opening into the plasma generating space 45 is formed in the lower portion of the upper shower plate 42. Also, the lower heat transfer member 71 is fastened while a screw 77 including an insulator is screwed into the lower shower plate 41 from the top side of the upper shower plate 42 through the lower heat transfer member 71. The screw 77 has a hole 78 passing therethrough in the axial direction. A gas hole 41c that communicates with the hole 78 of the screw 77 is formed in the lower plate 41. Also, the upper heat transfer member 72 is fastened with a metallic screw 92 that has a hole 93 passing therethrough in the axial direction. A gas hole 72a opening into the gas flow path 91 is formed in the upper heat transfer member 72.

In the present embodiment, the processing gas that is to be turned into plasma may be supplied to the plasma generating space 45 via the hole 93, the gas hole 72a, the gas flow path 91, and the gas holes 42b. Meanwhile, the processing gas that is not to be turned into plasma may be supplied to the lower space 11 which is a processing space, through the gas flow path 62, the gas diffusion space 46, the hole 78, and the gas hole 41c without passing through the plasma generating space 45.

For example, in the film formation processing of CVD or ALD, in some cases, the raw material gas is not planned to be turned into plasma but the reaction gas is planned to be turned into plasma. In such a case, according to the present embodiment, the reaction gas may be excited into plasma in the plasma generating space 45, and the raw material gas may be supplied to the lower space 11 without passing through the plasma generating space 45.

Also, in the above description, an example is illustrated in which the gas that is to be turned into plasma is supplied to the gas flow path 91 communicating with the plasma generating space 45, via the gas hole 72a provided in the upper heat transfer member 72, but the present disclosure is not limited to this.

### Fourth Embodiment

Next, a fourth embodiment will be described.

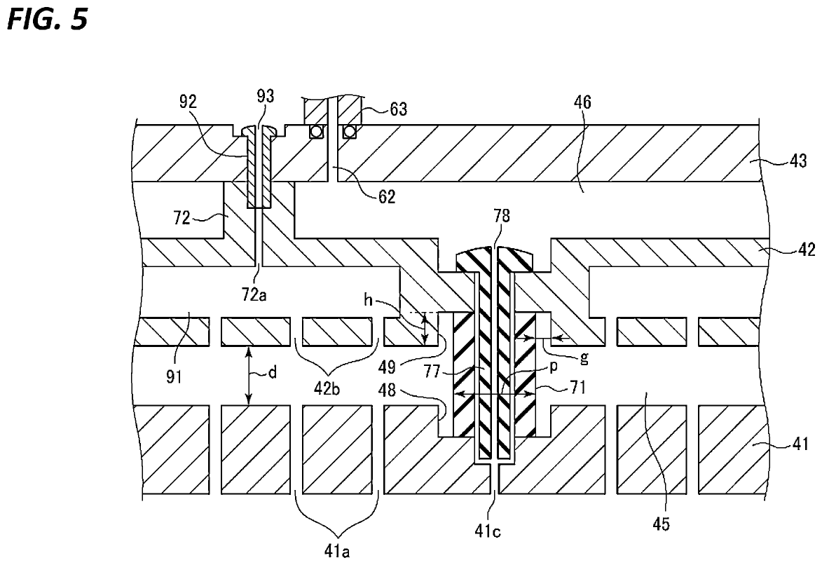

In the present embodiment, preferred ranges of shape factors related to the lower heat transfer member 71 are defined. FIG. 5 is a cross-sectional view illustrating a main part of a plasma processing apparatus according to the fourth embodiment. Also, for convenience, although FIG. 5 is based on FIG. 4 of the third embodiment, even if it is based on FIGS. 1 to 3 of the first embodiment or the second embodiment, the present embodiment is not changed.

The lower heat transfer member 71 is fitted into the recess 48 provided in the lower shower plate 41 and into the recess 49 provided in the upper shower plate 42, and the length of the lower heat transfer member 71 is longer than the interval (inter-electrode distance) between the lower shower plate 41 and the upper shower plate 42. Also, gaps g are formed between the side surface of the lower heat transfer member 71 and the side surfaces of the recess 48 and the recess 49. In this manner, due to the fact that the length of the lower heat transfer member 71 is longer than the inter-electrode distance and the gap g is provided in the fitting portion, it is possible to suppress an increase in parasitic capacitance caused by the installation of the lower heat transfer member 71 that is an insulator. Then, plasma distribution deterioration caused by a bias of radio-frequency current in the plasma generating space 45 is easily avoided.

It is desirable that the gaps g between the side surface of the lower heat transfer member 71 and the side surfaces of the recess 48 and the recess 49 are smaller than the sheath thickness of plasma (0.1 to 1 mm). That is, since plasma distribution may deteriorate if plasma enters the gap g, the gap g is made smaller than the sheath thickness to suppress intrusion of plasma into the gap g.

As illustrated in FIG. 5, when the depth of the lower heat transfer member 71 fitted into the lower shower plate 41 and the upper shower plate 42 is h and the interval (inter-electrode distance) between the lower shower plate 41 and the upper shower plate 42 is d, it is desirable that h>0.1d. When this relationship is satisfied, it is possible to further enhance the effect of reducing the parasitic capacitance caused by providing the fitting portion.

Also, when the diameter of the lower heat transfer member 71 is p, it is desirable that h<3p. If the depth h of the fitting portion is greater than 3p, the parasitic capacitance hardly changes even if the depth h of the fitting portion is changed, but the thermal resistance of the lower heat transfer member 71 increases.

### Other Applications

Although embodiments have been described above, the embodiments disclosed herein should be considered to be illustrative and not restrictive in all aspects. The above embodiments may be omitted, replaced, or modified in various forms without departing from the scope and spirit of the appended claims.

For example, in the above embodiments, descriptions have been made on an example in which the lower shower plate is a lower electrode, the upper shower plate is an upper electrode, and the processing gas is supplied to the plasma generating space in a shower form so that active species in the plasma are guided to the processing space in a shower form. However, the plasma processing apparatus is not limited to that of the above embodiments as long as it is a remote type in which plasma excitation occurs between parallel plate electrodes, and the plasma is introduced to the processing space. Also, in the structures according to the above embodiments, the sealing plate is provided above the upper shower plate via a gas diffusion space, and the upper heat transfer member is provided between the upper shower plate and the sealing plate so that the heat of the upper shower plate is transferred to the upper heat transfer member, but the present disclosure is not limited to this. Furthermore, descriptions have been made by taking film formation processing such as CVD or ALD as an example of plasma processing, but the present disclosure is not limited to this. For example, other plasma processing such as plasma etching may be used.

### DESCRIPTION OF SYMBOLS

10: processing container, 11; lower space (processing space), 20; stage, 24; exhaust device, 30; plasma generation unit, 41; lower shower plate (lower electrode), 42; upper shower plate (upper electrode), 50; radio-frequency power supply, 60; gas supply, 71; lower heat transfer member (heat transfer member), 72; upper heat transfer member, 100; plasma processing apparatus, W; substrate

1. A plasma processing apparatus comprising:
a processing container having a processing space where a substrate is disposed;
a plasma generator including a first electrode and a second electrode which are provided facing each other and are configured as parallel plate electrodes, and having a plasma generating space formed between the first electrode and the second electrode;
a radio-frequency power supply configured to form a radio-frequency electric field between the first electrode and the second electrode;
a gas supply configured to supply a processing gas for plasma generation in the plasma generating space;
a plasma introduction channel configured to introduce the plasma generated in the plasma generating space to the processing space; and
a heat transfer member including an insulator and configured to thermally connect the first electrode and the second electrode,
wherein plasma processing is performed on the substrate by the plasma introduced to the processing space.

2. The plasma processing apparatus according to claim 1, wherein the heat transfer member is provided to maintain a constant interval between the first electrode and the second electrode.

3. The plasma processing apparatus according to claim 1, wherein a plurality of heat transfer members is provided, and the plurality of heat transfer members are provided at axially symmetrical positions.

4. The plasma processing apparatus according to claim 1, wherein the heat transfer member is made of a material selected from aluminum nitride, alumina, silicon carbide, quartz glass, and yttria.

5. The plasma processing apparatus according to claim 1, wherein a thermal conductivity of the heat transfer member is selected according to a usage temperature.

6. The plasma processing apparatus according to claim 5, wherein the thermal conductivity of the heat transfer member is 100 W/K·m or more at a usage temperature ranging from 20° C. to 200° C.

7. The plasma processing apparatus according to claim 6, wherein the heat transfer member is made of aluminum nitride.

8. The plasma processing apparatus according to claim 1, wherein the heat transfer member is provided to suppress generation of parasitic capacitance.

9. The plasma processing apparatus according to claim 8, wherein the heat transfer member is fitted into a recess formed in the first electrode and the second electrode.

10. The plasma processing apparatus according to claim 9, wherein a gap between a side surface of the heat transfer member and the recess is smaller than a sheath thickness of the plasma.

11. The plasma processing apparatus according to claim 9, wherein h>0.1d is satisfied when a depth of the recess is h and an interval between the first electrode and the second electrode is d.

12. The plasma processing apparatus according to claim 9, wherein h<3p is satisfied when a depth of the recess is h and a diameter of the heat transfer member is p.

13. The plasma processing apparatus according to claim 1, wherein the plasma generator constitutes a shower head, the first electrode is a lower shower plate having a plurality of first gas holes, the second electrode is an upper shower plate having a plurality of second gas holes, and the first gas holes function as the plasma introduction channel
the plasma processing apparatus further comprises: a sealing member configured to seal the upper shower plate such that a gas diffusion space is present in a gap with the upper shower plate, and a second heat transfer member configured to thermally connect the upper shower plate and the sealing member,
the processing gas for plasma generation is supplied from the gas supply to the plasma generating space via the gas diffusion space and the second gas holes, and
the plasma generated in the plasma generating space is introduced to the processing space through the first gas holes serving as the plasma introduction channel.

14. The plasma processing apparatus according to claim 13, wherein among the first gas holes, those present in a peripheral portion of the heat transfer member are formed to be larger than others.

15. The plasma processing apparatus according to claim 13, wherein the heat transfer member is fastened to the lower shower plate and the upper shower plate with a screw having a through hole and including an insulator, a part of the processing gas passes through the through hole of the screw and is supplied to the processing space without passing through the plasma generating space, and a remainder of the processing gas is turned into plasma in the plasma generating space, and then is introduced to the processing space through the first gas holes serving as the plasma introduction channel.

16. The plasma processing apparatus according to claim 15, wherein the plasma processing is film formation processing in which a film is formed on the substrate by a reaction of a film-forming raw material gas and a reaction gas, and the part of the processing gas which is supplied to the processing space without passing through the plasma generating space is the film-forming raw material gas, and the remainder of the processing gas which is turned into the plasma in the plasma generating space is the reaction gas.

17. The plasma processing apparatus according to claim 1, wherein an interval between the first electrode and the second electrode is set to be smaller than a plasma skin depth such that the radio-frequency power is propagated as a quasi-TEM wave.

18. The plasma processing apparatus according to claim 17, wherein an interval d between the first electrode and the second electrode is set to satisfy the following formula:
$$d < 17 {( {λ}_{0} / R )}^{2} {V}_{0}^{1 / 5} {f}^{4 / 5}$$
wherein λ₀ is a wavelength (m) in a vacuum, V₀ is an amplitude (V) of a high frequency wave, f is a frequency (Hz), and R is a radius of a substrate.

19. The plasma processing apparatus according to claim 1, wherein a frequency of radio-frequency power supplied by the radio-frequency power supply is in a VHF to UHF band.

20. A plasma processing method comprising:
providing a plasma processing apparatus including:
a processing container having a processing space where a substrate is disposed;
a plasma generator including a first electrode and a second electrode which are provided facing each other and are configured as parallel plate electrodes, and having a plasma generating space formed between the first electrode and the second electrode;
a radio-frequency power supply configured to form a radio-frequency electric field between the first electrode and the second electrode;
a gas supply configured to supply a processing gas for plasma generation in the plasma generating space;
a plasma introduction channel configured to introduce the plasma generated in the plasma generating space to the processing space; and
a heat transfer member including an insulator and configured to thermally connect the first electrode and the second electrode;
forming a radio-frequency electric field between the first electrode and the second electrode;
supplying a processing gas to the plasma generating space and generating plasma by the radio-frequency electric field;
performing plasma processing on the substrate by introducing the plasma to the processing space via the plasma introduction channel; and
dissipating heat generated in the first electrode and the second electrode by the heat transfer member during the plasma processing.
